(19) United States
(12) Patent Application Publication
(10) Pub. No.: US 2011/0116213 A1
(43) Pub. Date: May 19, 2011

(54) DUAL-USE FIXING STRUCTURE AND ACCOMMODATING APPARATUS USING THE SAME

(75) Inventors: HUNG-FENG TAI, TAOYUAN COUNTY (TW); YEN-CHUAN CHEN, TAICHUNG CITY (TW)

(73) Assignee: ACCTON TECHNOLOGY CORPORATION, HSINCHU (TW)

(21) Appl. No.: 12/652,195

(22) Filed: Jan. 5, 2010

(30) Foreign Application Priority Data
Nov. 17, 2009 (TW) 098221392

(51) Int. Cl. H05K 7/00; F16M 13/00; F16M 13/02; A47F 7/00

(52) U.S. Cl. 361/679.01; 248/220.21; 248/222.14; 211/26

(57) ABSTRACT

The present invention relates to a fixing structure for electronic apparatuses and to an accommodating apparatus using the same. The electronic apparatus, such as a network apparatus, has fixing holes on both sides. Both ends of a fixing part have holes, respectively. Besides, one end of the fixing part has a slot. The fixing part is fixed on a support, such as the stands in a rack, or on a fixing surface, such as a wall, via the slot and the holes, and thus is positioned on the support or on the fixing surface. Hence, the electronic apparatus is fixed on the support or on the fixing surface. Accordingly, the dual-use fixing structure according to the present invention can fix the electronic apparatus on the support or on the fixing surface without the need of changing the fixing part, and hence reducing spatial limitations on installing electronic apparatuses. Additionally, the holes can be further used to reinforce fixing firmness when the electronic apparatus is hung through the slot of the fixing part.

### FIELD OF THE INVENTION

The present invention relates to a fixing structure, and particularly to a fixing structure for electronic apparatuses and to an accommodating apparatus using the same.

### BACKGROUND OF THE INVENTION

With the rapid development of information technology, in addition to significant progress in personal computers such as desktop computers or notebook computers, e-business has become a trend and personal computers cannot satisfy the specific demands of business users. Thereby, in modern prosperous communication technologies of varied types, because of its capability of transmitting a great deal of various data such as text, voice, or images immediately, the Internet has become one of main communicating ways for people. In an environment providing internet access to multiple people, such as in the corporate offices, schools, or homes, a network hub will be used to build up a local area network (LAN) for file sharing. Besides, the network hub is connected to a network modem for connecting to the Internet by dialing up or the leased line. By switching/routing in the network hub, the purpose of providing internet access to multiple people can be achieved.

When the number of servers connected in the LAN is huge, multiple network hubs can be utilized. For the convenience of management and maintenance, a cabinet with power supplies will be usually used for arranging various network connection apparatuses, such as network hubs, network modems, servers, gateways, and routers, in a single place.

Generally, system administrators will adopt a rack for installing and accommodating the network connection apparatuses for centralized management of the apparatuses. Thereby, the management efficiency can be enhanced.

In addition, when the network connection apparatuses, such as network hubs, are to be installed in small offices or places, if the network hubs are placed on the floor, the apparatuses are vulnerable to dust accumulation or humidity problems, which will shorten the lifetime of the network hubs. Furthermore, the apparatuses on the floor will also interfere the pathways of people, causing great inconvenience.

Accordingly, no matter the network hubs or other network apparatuses are to be installed centrally in racks or placed individually in respective offices, it is required to design a structure for installing the apparatuses with flexibility as well as convenience in various installation conditions.

### SUMMARY

An objective of the present invention is to provide a dual-use fixing structure and an accommodating apparatus using the same. By using a fixing part, electronic apparatuses, such as network apparatuses, can be fixed on a support, such as a rack, or on a fixing surface, such as a wall, respectively.

In order to achieve the objective described above, the present invention provides a dual-use fixing structure and an accommodating apparatus using the same for electronic apparatuses, which disclose a fixing part for fixing an electronic apparatus on a support or on a fixing surface without the need of using different fixing parts according to different carriers or fixing methods. Thereby, the electronic apparatuses can be installed in varied environments and be used with convenience in various regions, eliminating spatial limitations on the electronic apparatuses. In addition, when the fixing part is used for hanging the electronic apparatuses, the electronic apparatuses are screwed tight with the fixing part via a plurality of holes on the fixing part, and thus reinforcing hanging firmness. Consequently, hanging swing can be avoided.

### BRIEF DESCRIPTION OF THE DRAWINGS

FIG. 1 shows a schematic diagram of a fixing part according to a preferred embodiment of the present invention;

FIG. 2A shows an electronic apparatus fixed on a support according to a preferred embodiment of the present invention;

FIG. 2B shows a partial enlarged view of FIG. 2A;

FIG. 3A shows an electronic apparatus fixed on a wall according to another preferred embodiment of the present invention;

FIG. 3B shows a partial enlarged view of FIG. 3A;

FIG. 3C shows a partial enlarged view of FIG. 3A;

FIG. 4A shows a structural schematic diagram of a fixing part according to another preferred embodiment of the present invention; and

FIG. 4B shows a structural schematic diagram of a fixing part according to another preferred embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

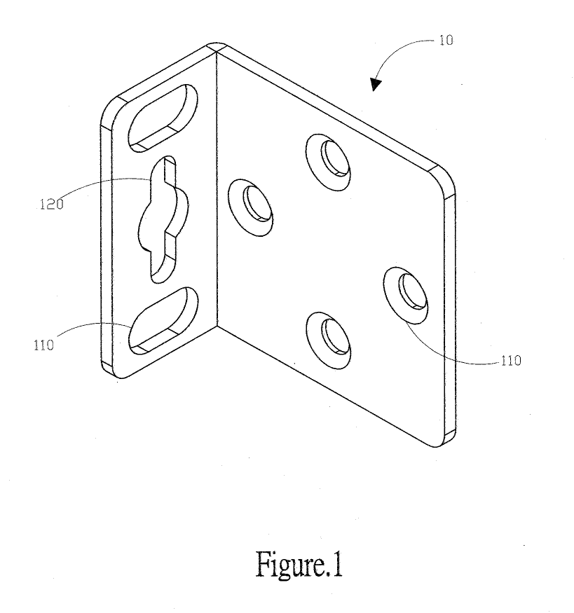

FIG. 1 shows a schematic diagram of a fixing part according to a preferred embodiment of the present invention. As shown in the figure, the present invention provides a dual-use fixing structure for an electronic apparatus. In present preferred embodiment of invention, the fixing part 10 is, for example, a rack mounting kit. According to the present invention, the fixing part 10 is provided with at least a hole 110 on both ends. According to the present preferred embodiment, a plurality of holes 110 are taken as an example. Besides, one end of the fixing part 10 has a slot 120 with the width at the middle greater than the width at both of its ends. The fixing part 10 is L-shaped according to the present preferred embodiment. Moreover, the fixing part 10 has two types of embodiments. One is to fix an electronic apparatus on a support, such as the stands in a rack, via two fixing parts 10; and the other is to fix an electronic apparatus on a fixing surface, such as a wall, via two fixing parts 10.

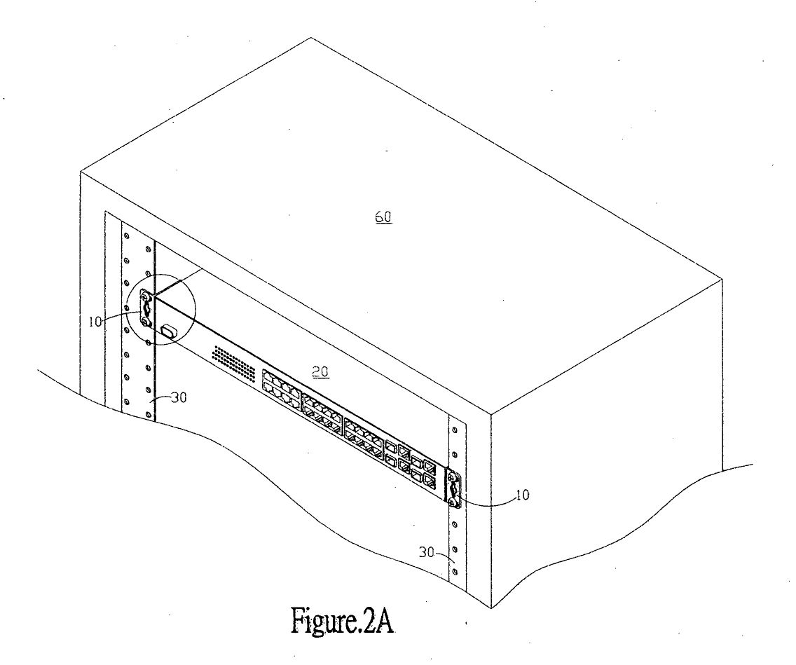

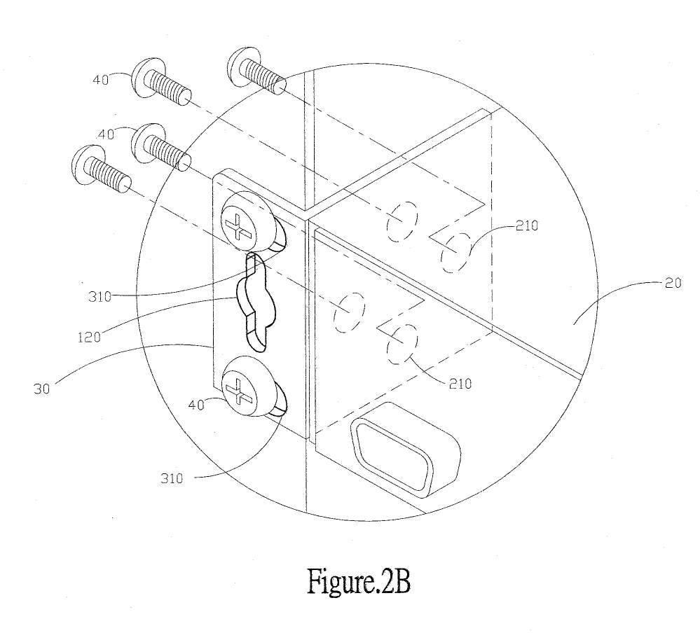

FIG. 2A shows an electronic apparatus fixed on a support according to a preferred embodiment of the present invention; and FIG. 2B shows a partial enlarged view of FIG. 2A. As shown in the figures, an electronic apparatus 20 is fixed on two supports 30. In this preferred embodiment, the electronic apparatus 20 is a network connection apparatus, such as a switch. According to the present preferred embodiment, the supports 30 are the stands of an accommodating apparatus 60, such as a rack. According to other embodiments, the support 30 can be a structure for fixing the electronic apparatus by screwing. Each of two supports 30 has at least a positioning hole 310. In addition, a plurality of fixing holes 210 are disposed on two corresponding ends of two sides of the electronic apparatus 20. By using a plurality of screws 40, the plurality of holes 110 on one end of the fixing part 10 are connected with the fixing holes 210 for fixing the fixing part 10 on the electronic apparatus 20. Then by using the plurality of screws 40, the plurality of holes 110 on the other end of the fixing part 10 are connected with the positioning holes 310 of the supports 30 for fixing the fixing part 10 on the two supports 30. Thereby, by the connection method described above, the electronic apparatus 20 is conveniently fixed on the two supports 30 via the two fixing parts 10.

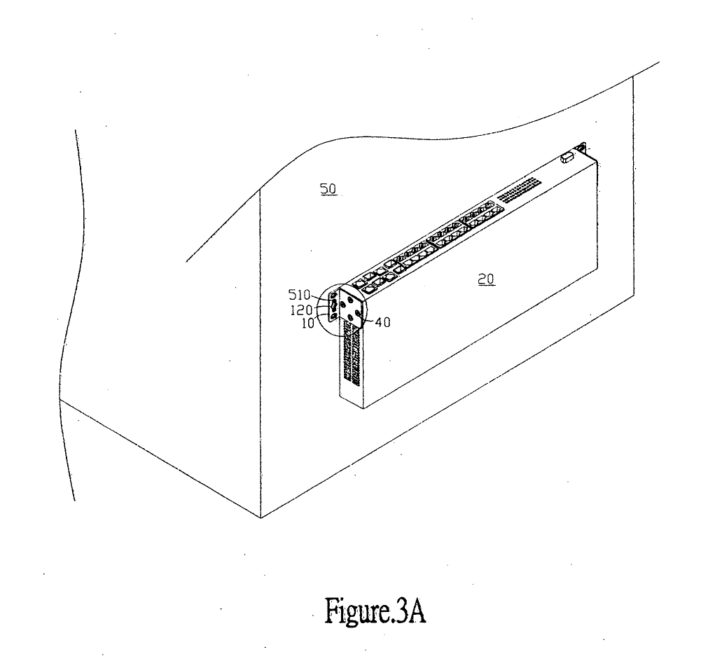

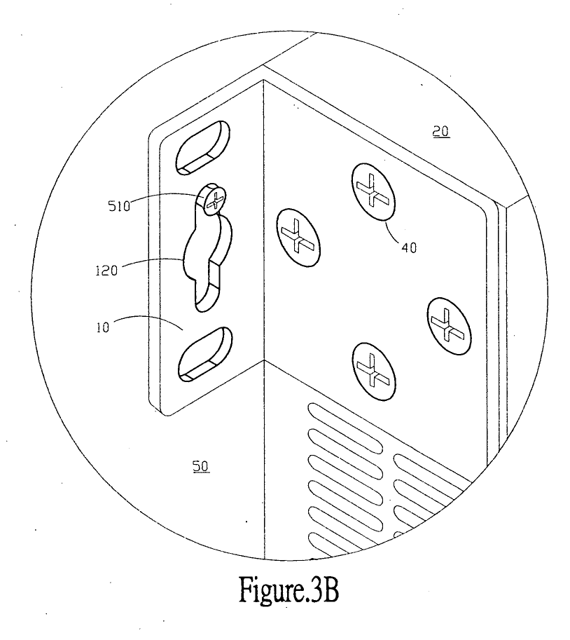

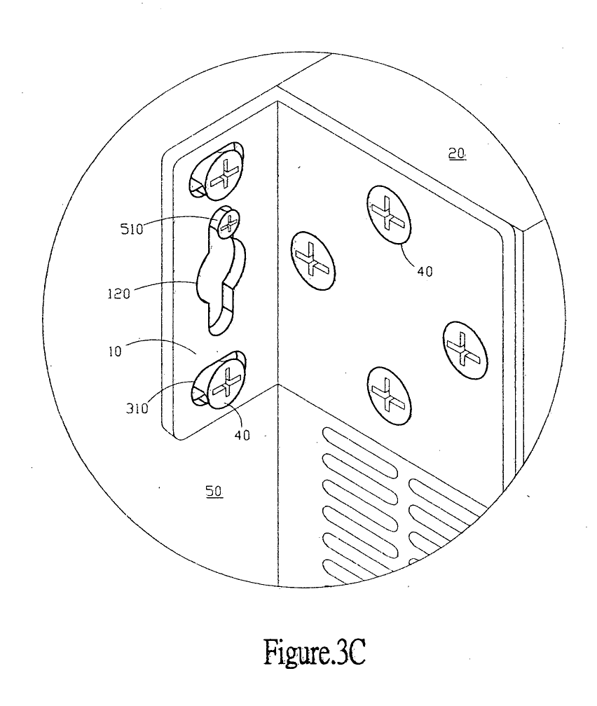

FIG. 3A shows an electronic apparatus fixed on a wall according to another preferred embodiment of the present invention; and FIG. 3B shows a partial enlarged view of FIG. 3A. As shown in the figures, an electronic apparatus 20 is fixed on a fixing surface 50. In present preferred embodiment, the fixing surface 50 is, for example, a wall. A plurality of fixing holes 210 are disposed on two corresponding ends of two sides of the electronic apparatus 20. By using a plurality of screws 40, the plurality of holes 110 on one end of the fixing part 10 are connected with the fixing holes 210 for fixing the fixing part 10 on the electronic apparatus 20. Besides, two parallel supporting members 510, such as screws or hooks, are disposed on the fixing surface 50. By taking advantage of the feature of greater width at the center of the two slots 120 on the two fixing parts 10 than at both ends, the electronic apparatus 20 can be hung and fixed on the two supporting members 510. Thereby, the electronic apparatus 20 can be hung or screwed tight (not shown in the figures) on the fixing surface 50 with ease. Additionally, the plurality of screws 40 can be further used to reinforce fixing firmness (as shown in FIG. 3C).

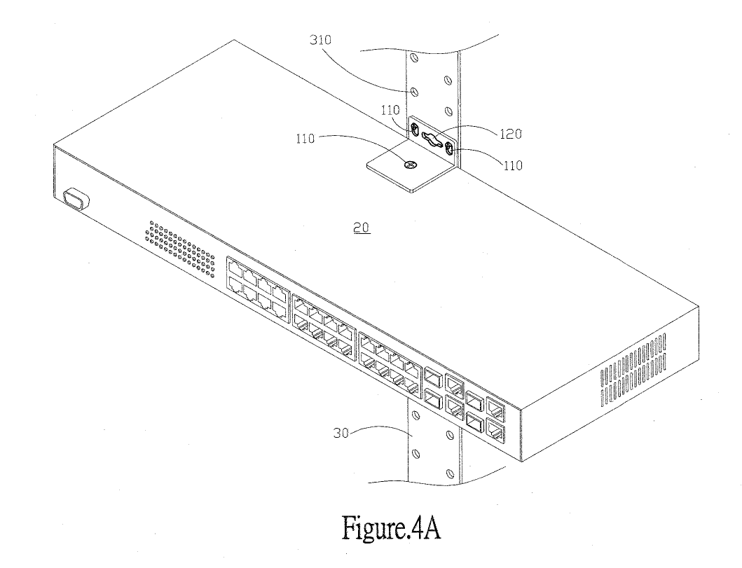

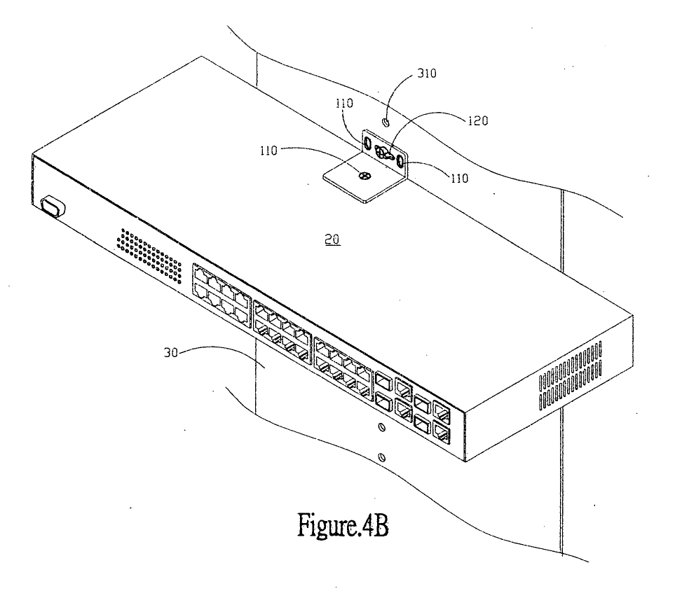

FIGS. 4A and 4B show structural schematic diagrams of a fixing part according to another preferred embodiment of the present invention. As shown in FIG. 4A, the number of the plurality of positioning holes 310, the fixing hole 210, or the plurality of holes 110 can be changed to be single or multiple depending on the fixing method adopted. According to the present preferred embodiment, the fixing part 10 includes only two holes 110 and a slot 120. The two holes 110 are disposed on both ends of the fixing part 10. One hole 110 on one end of the fixing part 10 is screwed on the electronic apparatus 20, while the hole 110 on the other end of the fixing part 10 is screwed on the support 30. Alternatively, as shown in FIG. 4B, one hole 110 on one end of the fixing part 10 is screwed on the electronic apparatus 20, while the other end of the fixing part 10 is hung on the support 30 through the slot 120.

To sum up, the present invention uses the fixing part 10 for fixing the electronic apparatus 20 on the support 30 (for example, a rack) or on the fixing surface (for example, a wall). Thereby, the fixing part 10 has a dual-use function. Additionally, if need, the screw 40 can be further used to reinforce fixing firmness when the electronic apparatus 20 is hung through the slot 120 of the fixing part 10.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A dual-use fixing structure, and comprising:
an electronic apparatus, having at least a fixing hole; and
a fixing part, having at least a hole and a slot at one end, and having at least a hole at the other end;
where when said fixing part is fixed on a support, said hole connects with a positioning hole of said support; or when said fixing part is fixed on a fixing surface, one end of said fixing part connects with a supporting member of said fixing surface through said slot, and the other end of said fixing part connects with said fixing hole of said electronic apparatus via said hole.

2. The dual-use fixing structure of claim 1, wherein said fixing part is L-shaped.

3. The dual-use fixing structure of claim 1, wherein said hole is connected with said positioning hole by screwing.

4. The dual-use fixing structure of claim 1, wherein said hole is connected with said fixing hole by screwing.

5. The dual-use fixing structure of claim 1, wherein the width at the center of said slot is greater than the width at both ends of said slot.

6. The dual-use fixing structure of claim 1, wherein said electronic apparatus is a network connection apparatus.

7. The dual-use fixing structure of claim 1, wherein said support is included by an accommodating apparatus for fixing.

8. The dual-use fixing structure of claim 7, wherein said accommodating apparatus is a rack accommodating said electronic apparatus.

9. The dual-use fixing structure of claim 1, wherein said supporting member of said fixing surface is included by an accommodating apparatus for fixing.

10. The dual-use fixing structure of claim 9, wherein said accommodating apparatus is a rack accommodating said electronic apparatus.

11. An accommodating apparatus, which has at least a support having at least a positioning hole, comprises: an electronic apparatus, having at least a fixing hole on one side, including at least a fixing part with a hole on both ends, respectively, said hole connecting with said positioning hole of said support at one end of said fixing part, said hole connecting with said fixing hole of said electronic apparatus at the other end of said fixing part, and said fixing part having a slot at the end connecting with said support.

12. The accommodating apparatus of claim 11, wherein said fixing part is L-shaped.

13. The accommodating apparatus of claim 11, wherein said hole is connected with said positioning hole by screwing.

14. The accommodating apparatus of claim 11, wherein said hole is connected with said fixing hole by screwing.

15. The accommodating apparatus of claim 11, wherein the width at the center of said slot is greater than the width at both ends of said slot.

16. The accommodating apparatus of claim 11, wherein said electronic apparatus is a network connection apparatus.

17. A rack for accommodating network apparatuses, comprising a support or a fixing surface, said support having at least a positioning hole, said fixing surface having at least a supporting member, and comprising:
a network connection apparatus, having a fixing hole on at least one side; and
a fixing part, having a hole at one end, and having a hole and a slot at the other end;
where when said network connection apparatus is fixed on said support, said hole at one end of said fixing part connects with said positioning hole of said support, and said hole at the other end of said fixing part connects with said fixing hole of said network connection apparatus; when said network connection apparatus is fixed on said fixing surface, said slot at one end of said fixing part connects with said supporting member of said fixing surface, and said hole at the other end of said fixing part connects with said fixing hole of said network connection apparatus.

18. The rack for accommodating network apparatuses of claim 17, wherein said fixing part is L-shaped.

19. The rack for accommodating network apparatuses of claim 17, wherein said hole is connected with said positioning hole by screwing.

20. The rack for accommodating network apparatuses of claim 17, wherein the width at the center of said slot is greater than the width at both ends of said slot.
